(19) United States
(12) Patent Application Publication
(10) Pub. No.: US 2008/0094057 A1
(43) Pub. Date: Apr. 24, 2008

(54) Position measurement system employing total transmitted flux quantization

(75) Inventor: Westley Ashe, Milton, VT (US)

Correspondence Address: H. JAY SPIEGEL - H. JAY SPIEGEL & ASSOCIATES, P.O. BOX 11, MOUNT VERNON, VA, 22121, US

(73) Assignee: ASCENSION TECHNOLOGY CORPORATION

(21) Appl. No.: 11/584,786

(22) Filed: Oct. 23, 2006

(51) Int. Cl. G01B 7/14; G01R 33/02

(52) U.S. Cl. 324/207.13

(57) ABSTRACT

A device for measuring the position (location and orientation) in the six degrees of freedom of a receiving antenna with respect to a transmitting antenna utilizing transmitter charge quantization. The transmitting component consists of a transmitting antenna of known location. The transmitting antenna is driven by a pulsed excitation. The receiving antenna measures the transmitted magnetic field. A computer then provides the correct position and orientation output.

### BACKGROUND OF THE INVENTION

The present invention relates to a position measurement system employing total transmitted flux quantization. The concept of using transmitting and receiving components with electromagnetic coupling is well known with respect to biomechanics and minimally invasive surgery. Sensors transmit position information regarding the location of instruments within the body. This information is then used by computing systems to precisely show the relative motions of the points in question, giving a surgeon valuable information regarding what actions to perform. When conductive materials are present, they generate eddy current fields, which may distort the received magnetic field signals, which potentially causes undesirable errors in the computed sensor position. Systems employing pulsed DC transmit waveforms and various magnetic sensor and signal processing techniques have been developed which reduce this effect. Sensor means for these and similar applications have measured both the H field and the derivative dH/dT field. The former is generally performed by a fluxgate magnetometer, hall effect, magneto optical, or magneto resistive sensor. The latter is generally performed by a coil followed by an integrator.

The following prior art is known to the applicant:

Geophysics vol. 41 pgs 287-299 (April 1976) describes the advantages and disadvantages of both DC field (H) measurement systems using a fluxgate magnetometer sensor means and dH/dT using a coil-integrator sensing means when employed in a pulse excited geomagnetic prospecting system. These systems do not determine the position of a sensor relative to a transmitter in 3 dimensions.

In U.S. Pat. No. 4,849,692 (Blood) and U.S. Pat. No. 4,945,305 (Blood), a position measuring system where a pulsed DC waveform is transmitted and the transmitted signal plus eddy field distortion is sensed using a DC responsive sensor. The transmitted waveform is held in a stable state while the eddy current fields decay to an insignificant level, at which time the sensed field value is digitized and sent to a computer for further processing. The disadvantage of such a system is that it requires energization of the transmitter during at least half of the steady state intervals, during which time considerable heat is generated. This heating limits the amount of signal that can be obtained from a given size transmitter.

U.S. Pat. No. 4,868,498 (Lusinchi) discloses an angular measurement device comprised of a magnetic transmitter element affixed to a rotating body. The transmitted signal is sensed by a coil whose output is then integrated to provide a reading of flux from the transmitter. This device is suited to measurement of the angular position of a rotating body, and is not capable of determining position in 3 dimensions.

U.S. Pat. No. 5,272,658 (Eulenberg) has, for the first sentence in its abstract, “A long term integrator, e.g. for integrating the voltage signal from a coil measuring magnetic induction . . . ”. Also on the front page of this patent is a figure which describes the use of a flux measuring coil, followed by an offset reducing amplifier, followed by a digital integrator comprised of an analog to digital converter and a DSP, the sum of which comprises a long term flux meter. This system does not describe a method or apparatus for determining position from the disclosed coil/integrator magnetic field measurement system, and only claims the long term integrator portion of the disclosure.

U.S. Pat. No. 5,453,686 (Anderson) A position measuring system is described which uses the same transmit waveform and position algorithm as disclosed in the '692 patent, with the addition of the coil-integrator sensor means similar to that disclosed in U.S. Pat. No. 5,272,658 and other prior art publications. The coil-integrator sensing means, which is compared to a fluxgate magnetometer as described in 1980 Geophysics vol. 45 no. 8 pg. 1281, is well known in art to produce results equivalent to a fluxgate magnetometer when measuring transient magnetic events. The transmitting waveform disclosed in the '692 patent is similar to that used in the '686 patent, thus it suffers from the same limitations due to heat generation.

U.S. Pat. No. 5,767,669 (Hansen and Ashe) discloses a system in which a triangular, non-steady state transmit waveform is utilized to overcome eddy current effects of nearby conductive metals. One embodiment of the device requires that a transmit waveform is produced such that eddy current conditions in the conductive metal environment reach a steady state condition during both the rising and falling edges of the transmit waveform. The patent also discloses numerous techniques of reducing the duration of either the rising and/or falling edges of the transmit waveform to increase the measurement rate. In all disclosed versions, the system requires that the integration reset and output digitization occur during transient conditions of the transmitted waveform. This requires a high bandwidth signal chain, and also requires very precise time synchronization between the transmitter and sensor signal processor. In motion capture applications, it is desirable to operate without physical connections between the transmitter and signal processor, such that a performer is unencumbered by cabling. Synchronization when using such a wireless configuration becomes significantly less precise than when a physical wire is used, and time jitter is often encountered. This time jitter results in less precise synchronization, which produces noise, offsets, and other undesirable effects on the system output.

All of the above rely on the instantaneous values of the magnetic field at a given point in time, proportional to the instantaneous current through the transmitter.

### SUMMARY OF THE INVENTION

The present invention relates to a position measurement system employing total transmitted flux quantization. The present invention particularly, in a preferred embodiment, is used to measure position and orientation of an object in a space in six degrees of freedom, namely, location in three co-ordinate directions being commonly defined by X, Y, and Z linear co-ordinates, and/or rotational movement commonly describes as azimuth, elevation, and roll relative to the transmit reference frame.

As used herein, “position” means location and/or orientation location.

In the preferred embodiment, a current pulse is sent through a transmitter. The reference quantity for computing ratiometric values from the sensors is the total flux time integral, in Tesla Seconds, which has been generated by the transmitter. During the steady state settling time, where the environmental eddy currents decay to zero, the transmitter is off and dissipates no power.

For a linear system, the flux time integral is proportional to the net electric charge which has passed through the transmitter. This charge quantity may be measured by sensing and integrating the transmitter current over time to yield the total coulombs through the transmitter. In the case of a non-linear transmitter, the transmitted flux time integral can be measured by double integrating the EMF from a sense coil on or near the transmitter. The first method is generally more economical, but may become inaccurate when if the transmitter has a ferromagnetic core which approaches saturation. The second method, while more complex, compensates for such core saturation effects.

The sensor is a coil of wire followed by a time gated double integrator. The double integrator starts integration at the beginning of the transmit pulse and is sampled at the end of the steady state settling time. The sampled value is proportional to the total flux time integral through the sensor, again in Tesla Seconds. This sampled value is free of eddy current distortion effects, as eddy current sources do not influence the double integral of sensor coil EMF provided sufficient time is given for them to decay to zero.

Because the transmitter does not dissipate heat during the steady state interval, during which no dB/dT signal is generated, the system can achieve equivalent signal to noise ratio of a traditional steady state pulsed DC system but with lower power dissipation.

Drift effects of the double integration, caused by real world, non-ideal components in the system, may be corrected by using two equal time transmit intervals, the first of which contains a positive current pulse and the second of which contains a negative current pulse. The sensor also contains two corresponding integration intervals. By making the time for the first integration equal to the time for the second integration, errors in the integration output due to constant offset sources are equal and of equal sign. The output components due to the transmitted magnetic field, however, are of opposite sign. Thus by subtracting the second integration result from the first, the offset components cancel and the signal components add. A further advantage of this technique is that dynamic errors due to moving the sensor coil in the earths field are also reduced, as are low frequency noise components due to the amplifiers and other circuit elements.

It is also possible to adjust the number of charge pulses through the transmitter in order to optimize signal to noise in environments with long eddy field decay times.

The instant device represents a departure from the prior art relating to such transmitting and receiving position and orientation devices by way of using the transmitted flux time integral as the quantity of reference. Prior art systems use the steady state instantaneous values of flux as the quantity of reference.

Accordingly, it is a first object of the present invention to provide a position measurement system employing total transmitted flux quantization.

It is a further object of the present invention to achieve higher signal to noise ratios for a given transmitter power dissipation. For a medical patient applied part, the improved signal to noise equates to a larger and more useful operating volume for a given transmitter temperature. This temperature limitation is imposed for patient safety reasons.

It is a yet further object of the present invention to provide a device for quantitatively measuring the position of receiving antennae relative to transmitting antennae with reduced transmitter power dissipation.

It is a still further object of the present invention to perform all critical control operations in the signal processor during the steady state of the transmitted waveform, such that the effects of time jitter and other system nonlinearaties are minimized.

It is a yet further object of the present invention to allow the construction of a simplified and efficient driver circuit which has reduced power dissipation during the steady state interval of the transmitter waveform.

These and other objects, aspects and features of the present invention will be better understood from the following detailed description of the preferred embodiment when read in conjunction with the appended drawing figures.

### BRIEF DESCRIPTION OF THE DRAWINGS

FIG. 1 depicts a schematic representation of the circuitry of the present invention.

FIG. 2 shows a chart depicting operation with multiple transmit charge pulses in a long eddy current settling environment.

FIG. 3 shows a chart showing the transmitter, sensor, and signal processor output waveforms of the instant invention.

FIG. 4 depicts the major elements of the disclosed invention.

FIG. 5 shows a chart depicting a mode of operation designed to optimize signal-to-noise ratio.

### SPECIFIC DESCRIPTION OF THE PREFERRED EMBODIMENT

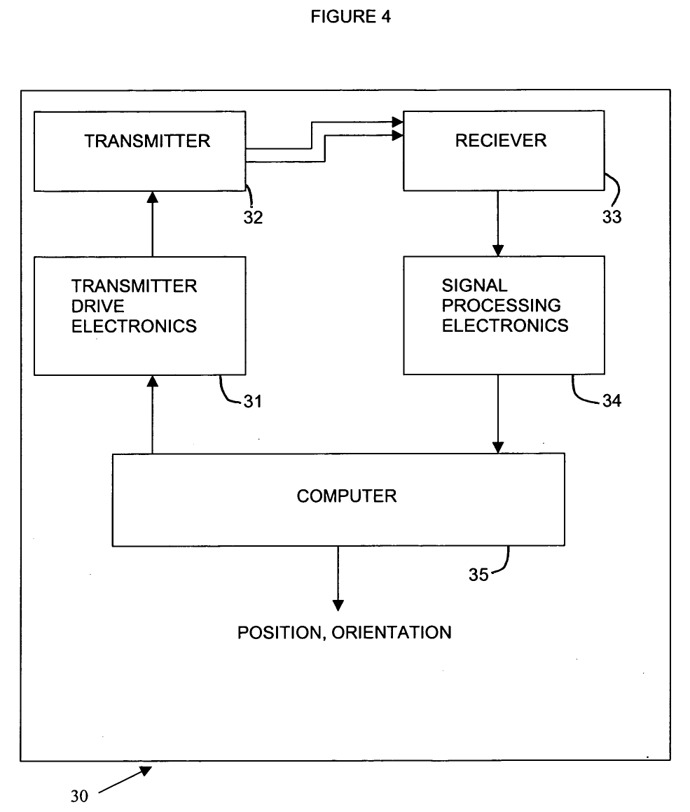

With reference, first, to FIG. 4, the schematic representation of the inventive system is generally designated by the reference numeral 30 and includes transmitter 32 driven by transmitter drive electronics 31 to transmit signals to receiver 33 which conveys those signals to signal processing electronics 34. Computer 35 controls the transmitter drive electronics 31 to operate the transmitter and receives data from signal processing electronics 34 to determine the spatial position and/or orientation of receiver 33 relative to transmitter 32. As used herein, position refers to position and/or orientation.

The implementation of transmitter 32 and receiver 33 is specific to a given system with respect to the number and location of axes in transmitter 32 and the number and location of sensor channels in receiver 33. In general, the number of transmit axes in transmitter 32 multiplied by the number of sensor channels in receiver 33 is at least equal to the number of degrees of freedom measured by the system. Individual axes for transmitter 32 are operated sequentially, meaning that a given measurement and compensation interval is completed for a given axis before energizing the next axis. Individual axes for receiver 33 may be measured simultaneously, such that individual axes are processed in parallel during a given transmit axis interval. As such, for clarity, the description of the preferred embodiment will focus on a single transmit axis and a single sensor channel which form the core of the present invention.

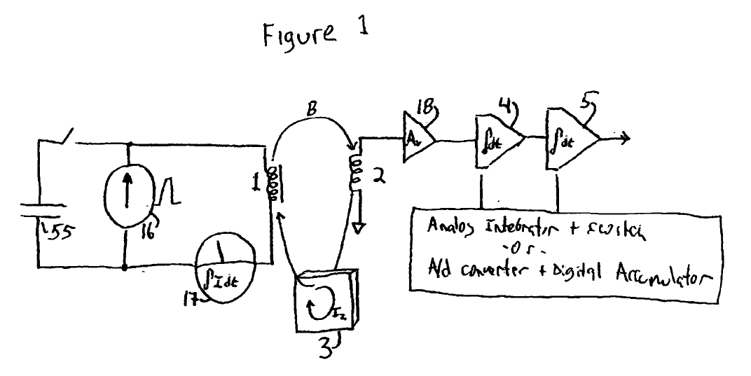

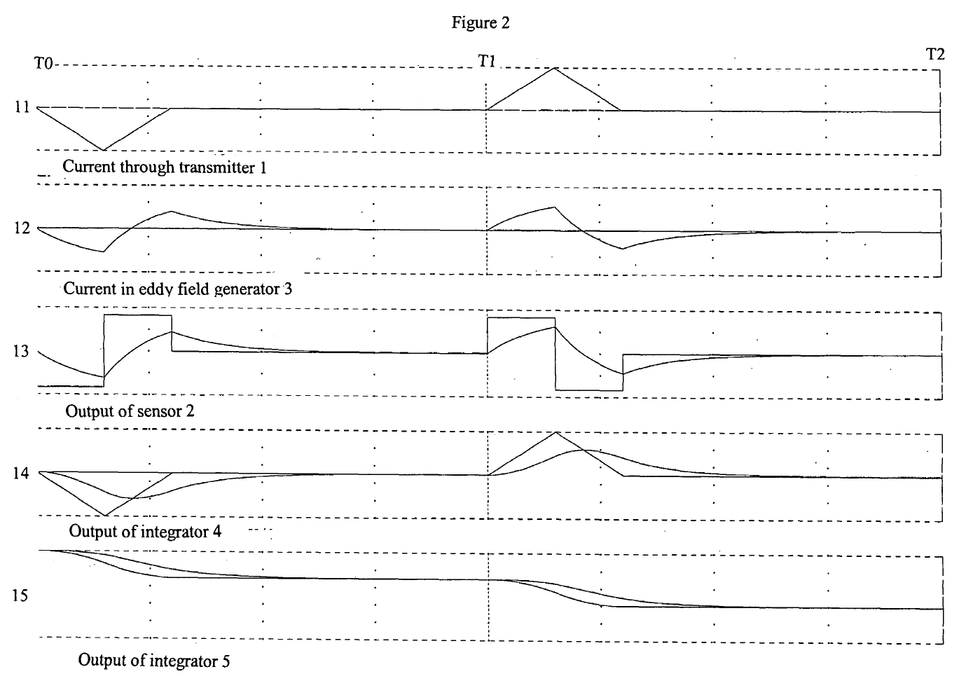

Referring to FIG. 1, linear transmitter 1 is constructed from a coil of wire. Driver 16 energizes transmitter 1 with a current pulse 11 (FIG. 2) having convenient amplitude, shape and duration. The pulse may or may not contain steady state components and can be of arbitrary shape. Integrating current meter 17 is used to measure the ampere second integral of said current pulse, which is then the net total electric charge in coulombs which have passed through transmitter 1. This quantity is proportional to the total flux time integral, in Tesla Seconds, generated by transmitter 1.

With further reference to FIG. 1, eddy field generator 3 represents a conductive object disposed in the operating volume which causes distortion in the magnetic field generated by transmitter 1 and received by sensor 2. With reference to FIG. 2, the graph designated by the reference numeral 12 represents the current response induced in eddy field generator 3 due to the magnetic field generated by transmitter 1.

Sensor 2 is sensitive to the time derivative of a magnetic field and is preferably a coil of wire. The graph 13 in FIG. 2 shows two output waveforms from sensor 2, one induced only by the field generated by transmitter 1, and one also including the effects of eddy field generator 3. It is clear from this waveform that the effects of eddy field generator 3 cause a significant change in the output of sensor 2.

Integrator 4 is started at time T0 and its output is shown in the graph 14 in FIG. 2. The distortion effects from eddy field generator 3 are evident in the graph 14. Second integrator 5 produces a waveform identified by the reference numeral 15. Note that the final value at time T1 from second integrator 5 is the same with or without the effects of eddy field generator 3.

The output of second integrator 5 is divided by the output of transmitter integrator 17 to form a ratio which is dependent only on the coupling between transmitter 1 and sensor 2. That output is independent of effects from eddy field generator 3 provided the interval T1−T0 is long enough to allow the current in eddy field generator 3 to decay to zero. It is also independent of the magnitude or shape of the current pulse through transmitter 1. This simplifies the design and construction of driver 16, as precise control over the current waveform is not needed.

Below, it is shown how a magnetic position measurement system employing the described method can be made immune from eddy current effects.

In a non-ideal system such as that of the preferred embodiment, the value from sensor 2 is amplified by amplifier 18, which for practical devices will output a non-zero output if fed a zero input, the so called offset voltage. This offset voltage, when double integrated by integrator 4 and second integrator 5, is a significant source of error. A method for eliminating this error is presented below.

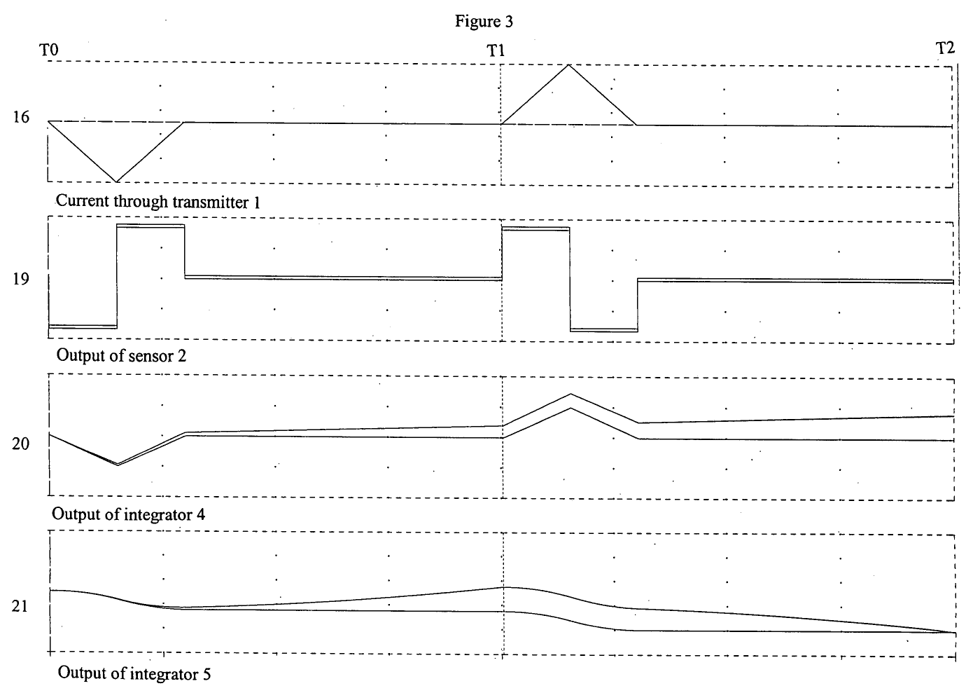

FIG. 3 shows parallel graphs of the system operation with an offset error due to amplifier 18, omitting the effects of eddy current generator 3 for clarity. Operation from T0 to T1 proceeds as previously described, with graph 19 showing the offset effects of imperfect amplifier 18. Graph 20 shows the output of integrator 4, and graph 21 shows the output of second integrator 5. It can be seen from graph 21 that the offset effects of imperfect amplifier 18 seriously degrade the output of second integrator 5 at time T1. This degradation can be eliminated by introducing a second cycle during T2−T1 in FIG. 3. Operation of the system proceeds as before with three changes. After the first cycle T1−T0, the output of second integrator 5 is stored. A second cycle, T2−T1 is then started. During this second cycle, driver 16 produces a current pulse of opposite polarity through transmitter 1. The gain of second integrator 5 is also inverted such that it becomes a de-integrator. The resulting waveform is shown during the T1 to T2 interval in FIG. 3. At time T2 in graph 21 it is seen that the offset error from imperfect amplifier 18 is removed. Provided that interval T1−T0=T2−T1, any constant rate drift in the output of second integrator 5, as would be caused by imperfect amplifier 18 or other sources, will be removed automatically.

It is noted that during the compensation interval T2−T1 it is not necessary to energize the transmitter to obtain a useful, eddy-response-free and drift-corrected output from second integrator 5 at time T2. This could simplify the construction of transmit driver 16. The penalty for this simplification is a reduction in signal-to-noise ratio, as there is no signal to measure during the second interval, as only the error terms are being measured and subtracted.

It is also noted that inverting the polarity of sensor 2 during second interval T2−T1, by some means such as analog switches or relays, could be employed instead of inverting the transmitter current. This would allow driver 16 to be of unipolar construction which would simplify its circuitry.

It is further noted that the system can be made to work with T1−T0 not equal to T2−T1. This would require a more complex but readily implemented drift measurement and compensation technique, readily implemented by those skilled in the art.

Also, use of a DC sensitive sensing means for sensor 2, such as a fluxgate magnetometer, magnetoresitive, or Hall effect senor, would allow the output of integrator 4 to be used in place of the output of integrator 5 in the system, with all other aspects of operation remaining the same. Second integrator 5 is then removed from the system.

Additionally, if the output of driver 16 were stable and repeatable, the transmit reference integrator 17 could be removed and a fixed numerical constant representing the known total transmitted flux time integral used instead. In this case, circuitry used to determine the total flux time integral would not be used and the output of second integrator 5 could be used directly to compute the position of sensor 2.

Driver 16 can be a controlled current source, stored charge in a capacitor which is discharged across the coils of transmitter 1, or a simple voltage source and a switch. The exact means by which a charge of electrons is moved through transmitter 1 would be determined by convenience and performance requirements.

In the preferred embodiment, transmitter 1 possesses a linear current to field relationship, such that the simpler current measurement and integration method can be employed accurately. If it were desirable to reduce the weight of transmitter 1, one method would be to employ thinner core material. This has the effect of creating higher flux density and this can result in a non-linear current to field transfer function as the flux density approaches saturation. In this case, current sense resistor 18 and integrator 16 could be replaced with a fixed magnetic sensor either integral with or external to the transmitter. If this sensor were DC sensitive, such as a magnetoresistive sensor, it would be followed by a single integrator. If it were derivative sensitive, such as a coil, it would be followed by two integrators. In either of the two latter cases, it is again possible to measure a value proportional to the total flux integral from transmitter 1.

Furthermore, the system can operate with moving permanent magnets in place of transmitter 1. The time derivative pulse is then created during each interval T1−T0 and T2−T1 by rotating the magnet at the start of each interval. The reference integral in this case could be made by a number of means obvious to those skilled in the art. If the magnet position were accurate enough and the positioning method repeatable enough, the reference integral could be omitted and a known constant employed.

When the distance between transmitter 1 and sensor 2 becomes close, amplifier 18 may saturate. If the gain bandwidth of amplifier 18 is reduced such that it acts as a lowpass filter, it is possible to operate transmitter 1 in a manner such that the peak charge rate and/or duration of each charge pulse is reduced. This effectively spreads the charge over a longer period of time and reduces the peak level, which results in amplifier 18 staying within a linear range. It is also possible to increase or decrease the number of these smaller pulses, which may further benefit the signal to noise ratio as explained earlier.

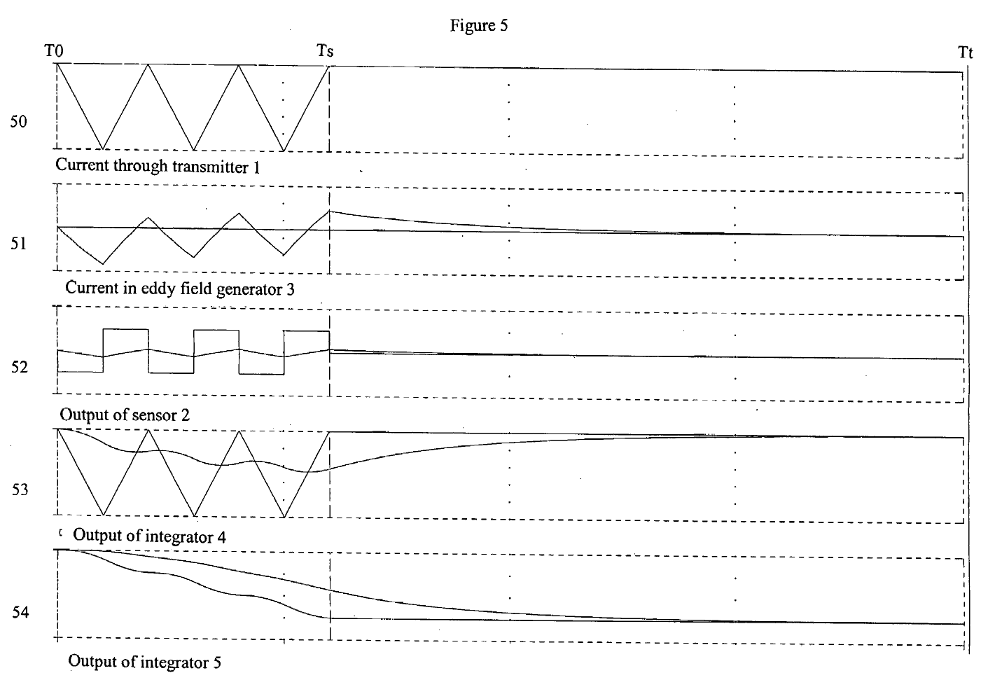

In order to optimize the signal-to-noise ratio of the system in the presence of conductive metals, a mode of operation is shown in FIG. 5. In this mode, driver 16 outputs a sequence of pulses through transmitter 1 during interval Ts shown in graph 50. Graph 51 shows the eddy current value in nearby conductive objects. Sensor 2 produces a signal Electromotive Force (EMF) defined as Es from transmitter 1 during interval Ts shown in graph 52. It also produces an EMF due to eddy current fields, which is summed with Es. It also produces a thermal noise EMF (En) which is added to Es during the entire interval Tt. The signal-to-noise (S/N) ratio of sensor 2 is defined as the average. ratio of Es/En during interval Tt. For a triangle waveform transmit pulse sequence shown in graph 50, the RMS value of Es (52) is constant during Ts and zero during the transmitter OFF period Td. The average signal-to-noise is then S/N=Ts*Es/En(Ts+Td). In a real system, the output noise of second integrator 5 is proportional to K*Tt 1.5*sqrt (En²+Ea²), where K is the total gain of the signal chain consisting of amplifier 18, first integrator 4, and second integrator 5. Ea is the noise characteristic of amplifier 18, which is a complex function of frequency, very device specific, and subject to system tradeoffs. Graph 54 shows the eddy current errors decaying to zero at the output of second integrator 5. It is seen that Td must be lengthened as the eddy current decay times become longer, thus the average S/N will become lower due to the lower signal duty cycle Ts/Tt. Operating driver 16 to output a sequence of pulses through transmitter 1 results in lengthening of Ts. If Td must be fixed at an optimum value to remove eddy current errors, then lengthening of Ts increases the signal duty cycle and thus the S/N from sensor 2. There is a practical limit on how long Tt can be made before the T 1.5 term in the noise equation for second integrator 5 cancels the benefit of increasing the Ts/Tt duty cycle by lengthening Ts. The optimum Ts/Tt signal duty cycle in the preferred embodiment is determined empirically by measuring the S/N ratio and adjusting Ts and Tt until the S/N is maximized and eddy current distortion is minimized in a given environment.

Graph 53 is of the output of first integrator 4, not really used in the text as it is sort of an intermediate product, serving as the input of second integrator 5 from which the signal of interest is taken.

As such, an invention has been disclosed in terms of a preferred embodiment that fulfills each and every one of the objects of the present invention as set forth hereinabove and provides a new and useful position measurement system employing total transmitted flux quantization of great novelty and utility.

Of course, various changes, modifications and alterations in the teachings of the present invention may be contemplated by those skilled in the art without departing from the intended spirit and scope thereof.

As such, it is intended that the present invention only be limited by the terms of the appended claims.

1. Magnetic position measurement system comprising:
a) a magnetic transmitter connected to a charge source, said source causing a net cumulative electric charge to flow through said transmitter over an interval of time, said transmitter producing a transmitted net magnetic flux time integral;
b) a sensor outputting a sensed value proportional to said transmitted net magnetic flux time integral over said interval of time;
c) a processor operating on said sensed value from said sensor and outputting values of position and orientation for said sensor relative to said transmitter.

2. The system of claim 1, wherein said net cumulative electric charge is measured by sensing and integrating, as a function of time, current flowing through said transmitter.

3. The system of claim 1, wherein said net cumulative electric charge is pre-measured and stored in a capacitor, said capacitor discharging into said transmitter in such a manner as to produce a non-zero net cumulative electric charge value through said transmitter.

4. The system of claim 2, wherein said transmitter possesses a non-linear current-to-transmitted-field transfer function, non-linear properties of said transfer function being corrected by a correction coefficient.

5. The system of claim 1, further including a double integrator, determination of said transmitted net magnetic flux time integral being carried out by double integrating output of a fixed coil disposed in a vicinity of said transmitter.

6. The system of claim 1, wherein said transmitter possesses a non-linear current-to-transmitted-field transfer function.

7. The system of claim 1, further including an integrator, determination of said transmitted net magnetic flux time integral being carried out by integrating output of a fixed DC responsive magnetic sensor disposed in a vicinity of said transmitter.

8. The system of claim 1, wherein said charge source produces current waveforms having non-zero steady state intervals.

9. The system of claim 1, wherein said charge source produces current waveforms devoid of non-zero steady state intervals.

10. The system of claim 1, wherein said sensor is responsive to a time derivative of a magnetic field from a coil followed in series by a double integrator.

11. The system of claim 1, wherein said sensor is responsive to steady state magnetic fields, such as one chosen from the group consisting of a fluxgate magnetometer, hall effect sensor, magnetoresistive sensor, magneto-optical sensor, followed by an integrator.

12. The system of claim 11, wherein said integrator includes an A/D converter and a digital accumulator.

13. The system of claim 11, wherein said integrator comprises an analog integrator followed by a sampling mechanism.

14. The system of claim 1, wherein said source produces waveforms having characteristics chosen from the group consisting of triangular, exponential, partial sinusoid, and trapezoidal amplitude vs. time.

15. A magnetic position measurement system employing:
a) a magnetic transmitter connected to a driver, said driver causing a net cumulative electric charge to flow through the transmitter over a first interval of time, said first interval ending with a steady state interval;
b) a sensor outputting a sensed value proportional to said net cumulative electric charge through said transmitter over said first interval of time, said sensed value being sampled at an end of said steady state interval;
c) a processor which operates on said sensed value and outputting values of position and orientation for said sensor relative to said transmitter.

16. The system of claim 15, wherein no net current charge passes through said transmitter during said steady state interval.

17. The system of claim 15, further including a second interval of time, said sensed value comprising a first sensed value, said sensor outputting a second sensed value proportional to said net cumulative electric charge through said transmitter over said second interval of time.

18. The system of claim 17, wherein said second interval of time is equal to said first interval of time, and said second sensed value is subtracted from said first sensed value.

19. The system of claim 17, wherein said driver causes a second net cumulative electric charge to flow through said transmitter during said second interval of time, said second interval ending with a steady state interval, and said second net cumulative electric charge flowing through said transmitter in a negative direction with respect to said first electric charge.

20. The system of claim 15, wherein said sensor is responsive to a time derivative of a magnetic field from a coil, followed in series by a double integrator.

21. The system of claim 15, wherein said sensor means comprises a sensor responsive to steady state magnetic fields, such as one chosen from the group consisting of a fluxgate magnetometer, hall effect sensor, magnetoresistive sensor, magneto-optical sensor, followed by an integrator.

22. The system of claim 15, wherein said integrator includes an A/D converter and a digital accumulator.

23. The system of claim 15, wherein said integrator comprises an analog integrator followed by a sampling mechanism.

24. The system of claim 15, wherein said driver produces waveforms having characteristics chosen from the group consisting of triangular, exponential, partial sinusoid, and trapezoidal amplitude vs. time.

25. A magnetic position measurement system employing:
a) a magnetic transmitter connected to a driver, said driver causing a net cumulative electric charge to flow through the transmitter over an interval of time, said net cumulative electric charge comprising a series of sequential charge pulses;
b) a sensor outputting a sensed value proportional to said net cumulative electric charge through said transmitter over said interval of time;
c) a processor operating on said sensed value from said sensor to output values of position and orientation for said sensor relative to said transmitter means.

26. The system of claim 25, wherein a number of said sequential charge pulses is varied as a function of said sensed value.

27. The system of claim 25, wherein a number of said sequential charge pulses is varied as a function of sensor signal-to-noise ratio.

28. The system of claim 25, wherein a number of said sequential charge pulses is varied as a function of environmental eddy current settling time.
